(19) United States
(12) Patent Application Publication
(10) Pub. No.: US 2024/0278536 A1
(43) Pub. Date: Aug. 22, 2024

(54) BISMALEIMIDE COMPOSITION, CURED PRODUCT, SHEET, LAMINATED BODY, AND FLEXIBLE PRINTED WIRING BOARD

(71) Applicants: Resonac Corporation, Tokyo (JP); LG Innotek Co.,LTD., Seoul (KR)

(72) Inventors: Kitaru SATO, Tokyo (JP); Takaaki SAKAI, Tokyo (JP); Kenji FURUYA, Tokyo (JP); Hideyuki MAEDA, Tokyo (JP); Hiroshi KODAIRA, Tokyo (JP)

(21) Appl. No.: 18/569,894

(22) PCT Filed: Jun. 15, 2021
(86) PCT No.: PCT/JP2021/022763

§ 371 Date: Dec. 13, 2023

(51) Int. Cl. B32B 15/08; H05K 1/03

(52) U.S. Cl. CPC B32B 15/08; H05K 1/0373; H05K 1/0393; B32B 2250/02; B32B 2264/1021; B32B 2264/301; B32B 2264/4021; B32B 2379/08; B32B 2457/08; H05K 2201/0154; H05K 2201/05

(57) ABSTRACT

Provided is a bismaleimide composition including: a bismaleimide resin (A) having a structure derived from an aromatic tetracarboxylic acid (a1), a dimer diamine (a2), and a maleic anhydride (a3); and silica particles (B) surface-treated with phenylaminosilane, in which the silica particles (B) have an average particle diameter of 100 nm or less, the silica particles (B) have an maximum aggregation particle size of 20 μm or less, and a content of the silica particles (B) is 15% by mass or less based on a total solid content of the composition.

### TECHNICAL FIELD

The present invention relates to a bismaleimide composition, a cured product, a sheet, a laminated body, and a flexible printed wiring board.

### BACKGROUND ART

Flexible printed wiring boards (hereinafter, abbreviated to “FPC”) and multilayer wiring boards that use FPC have been used in manufactured products, such as mobile type communication equipment such as mobile telephones and smart phones, and base station devices thereof; network-related electronic equipment such as server routers; and large-sized computers.

In recent years, for those manufactured products, high-frequency electric signals are used in order to rapidly transmit and process large quantities of information; however, since high-frequency signals are very easily attenuated, it is required to devise suppression of transmission loss even in the above-described FPC, multilayer wiring boards, and the like.

Transmission loss can be distinguished between “dielectric loss” originating from an insulating material around a dielectric substance, that is, a conductor (copper circuit), and “conductor loss” originating from a copper circuit itself, and it is necessary to suppress both.

The dielectric loss is dependent on frequency as well as the dielectric constant and the dielectric loss tangent of the insulating material around the copper circuit. As the frequency is higher, it is necessary to use a material having a lower dielectric constant and a lower dielectric loss tangent as the insulating material.

On the other hand, the conductor loss is attributable to a skin effect, that is, a phenomenon in which the alternating current density at the copper circuit surface increases, and the resistance of the copper circuit grows larger, and the conductor loss becomes notable when the frequency exceeds 1 GHZ. A main countermeasure for suppressing the conductor loss is to smooth the copper circuit surface.

In order to suppress the dielectric loss, a material having a low dielectric constant and a low dielectric loss tangent may be used as the insulating material as described above, and as a such a material, specific polyimides have been hitherto used (see Patent Literatures 1 and 2).

### CITATION LIST

### Patent Literature

Patent Literature 1: Japanese Unexamined Patent Publication No. 2009-299040
Patent Literature 2: Japanese Unexamined Patent Publication No. 2014-045076

### SUMMARY OF INVENTION

### Technical Problem

For an insulating material, a low dielectric constant and a low dielectric loss tangent are required in order to use high frequency signals, and in order to secure reliability of the wiring board and to suppress warpage of the board, a low coefficient of thermal expansion (low CTE) is required. With regard to conventional insulating materials, it has been difficult to realize all of low dielectric constant, low dielectric loss tangent, and low coefficient of thermal expansion at high levels.

Thus, it is a main object of the present invention to provide a novel bismaleimide composition in which the dielectric constant and the dielectric loss tangent (hereinafter, the two may be collectively referred to as “dielectric characteristics”) are both low and the coefficient of thermal expansion (CTE) is low.

An object of the present invention is to provide a bismaleimide composition having low dielectric characteristics and a low coefficient of thermal expansion, and a cured product, a sheet, a laminated body, and a flexible printed wiring board, all of which use the bismaleimide composition.

### Solution to Problem

The inventors of the present invention have conducted a thorough investigation in order to solve the above-described problems, and as a result, the inventors have found that a bismaleimide composition including a bismaleimide resin (A) having a structure derived from an aromatic tetracarboxylic acid (a1), a dimer diamine (a2), and a maleic anhydride (a3); and silica particles (B) surface-treated with phenylaminosilane, in which the silica particles (B) satisfy specific conditions and the content of the silica particles (B) is in a predetermined range, has excellent low dielectric characteristics and a more excellent low coefficient of thermal expansion, thus completing the present invention.

That is, the present invention provides the following inventions.
[1] A bismaleimide composition including a bismaleimide resin (A) having a structure derived from an aromatic tetracarboxylic acid (a1), a dimer diamine (a2), and a maleic anhydride (a3); and silica particles (B) surface-treated with phenylaminosilane,
wherein the silica particles (B) have an average particle diameter of 100 nm or less,
the silica particles (B) have a maximum aggregation particle size of 20 μm or less, and
a content of the silica particles (B) is 15% by mass or less based on a total solid content of the composition.
[2] The bismaleimide composition as described in the above-described item [1], wherein the aromatic tetracarboxylic acid (a1) is a pyromellitic anhydride.
[3] The bismaleimide composition as described in the above-described item [1] or [2], wherein the dimer diamine (a2) is a compound represented by general formula (1) and/or general formula (2) below:

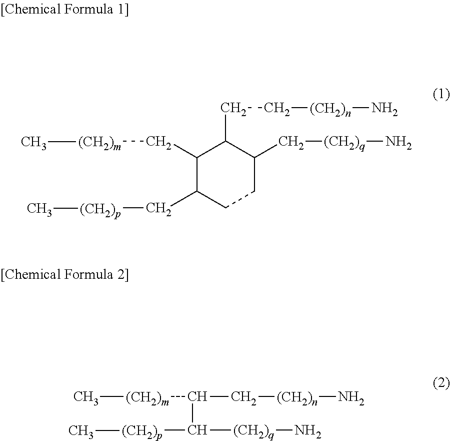

(in formulas (1) and (2), m, n, p, and q each represent an integer of 1 or more selected so that m+n=6 to 17 and p+q=8 to 19; and a bond indicated by a broken line means a carbon-carbon single bond or a carbon-carbon double bond, provided that when the bond indicated by the broken line is a carbon-carbon double bond, the structures of formula (1) and (2) are structures each having a number of hydrogen atoms bonded to each of the carbon atoms constituting the carbon-carbon double bond, the number of hydrogen atoms being obtained by subtracting 1 from the number shown in formula (1) or (2).)
[4] The bismaleimide composition as described in any one of the above-described items [1] to [3], wherein the bismaleimide resin (A) has a weight average molecular weight of 3000 to 25000.
[5] The bismaleimide composition as described in any one of the above-described items [1] to [4], further including a polymerization initiator (D).
[6] The bismaleimide composition as described in the above-described item [5], wherein the polymerization initiator (D) is an organic peroxide.
[7] A cured product of the bismaleimide composition as described in any one of the above-described items [1] to [6].
[8] A sheet including the bismaleimide composition as described in any one of the above-described items [1] to [6] and a base material.
[9] A laminated body obtained by further thermocompression bonding a metal foil to the sheet described in the above-described item [8].
[10] A flexible printed wiring board obtained by using the sheet described in the above-described item [8].
[11] A flexible printed wiring board obtained by using the laminated body described in the above-described item [9].

### Advantageous Effects of Invention

According to the present invention, a bismaleimide composition having low dielectric characteristics and a low coefficient of thermal expansion, and a cured product, a sheet, a laminated body, and a flexible printed wiring board, all of which use the bismaleimide composition, can be provided.

### DESCRIPTION OF EMBODIMENTS

Hereinafter, embodiments of the present invention will be described in detail.

### <Bismaleimide Composition>

A bismaleimide composition of the present embodiment includes a bismaleimide resin (A) (hereinafter, also referred to as “component (A)”) having a structure derived from an aromatic tetracarboxylic acid (a1) (hereinafter, also referred to as “component (a1)”), a dimer diamine (a2) (hereinafter, also referred to as “component (a2)”), and a maleic anhydride (a3) (hereinafter, also referred to as “component (a3)”); and silica particles (B) surface-treated with phenylaminosilane (hereinafter, also referred to as “component (B)”). The bismaleimide composition of the present embodiment may further include an organic solvent (C) (hereinafter, also referred to as “component (C)”). Furthermore, the bismaleimide composition of the present embodiment may further include a polymerization initiator (D) (hereinafter, also referred to as “component (D)”).

### (Component (A): Bismaleimide Resin)

Component (A) can be obtained by reacting component (a1) with component (a2) and component (a3).

As the component (a1), any compound known as a raw material of polyimide can be used. Specific examples include a pyromellitic anhydride and a compound represented by general formula (1) below:

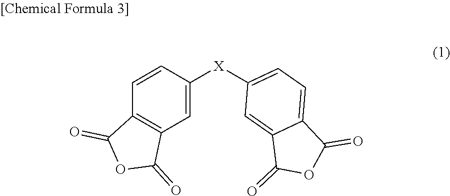

(in formula (1), X represents a single bond or at least one group selected from the following group.)

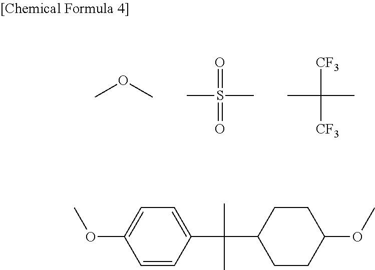

Examples of the compound represented by formula (1) include 4,4′-oxydiphthalic dianhydride, 3,3′,4,4′-diphenyl ether tetracarboxylic acid dianhydride, 3,3′,4,4′-diphenylsulfonetetracarboxylic acid dianhydride, 3,3′,4,4′-biphenyltetracarboxylic acid dianhydride, 2,2′,3,3′-biphenyltetracarboxylic acid dianhydride, 2,3,3′,4′-biphenyltetracarboxylic acid dianhydride, 2,3,3′,4′-diphenyl ether tetracarboxylic acid dianhydride, 2,3,3′,4′-diphenylsulfone tetracarboxylic acid dianhydride, 2,2-bis(3,3′,4,4′-tetracarboxyphenyl)tetrafluoropropane dianhydride, 2,2′-bis(3,4-dicarboxyphenoxyphenyl)sulfone dianhydride, 2,2-bis(2,3-dicarboxyphenyl)propane dianhydride, 2,2-bis(3,4-dicarboxyphenyl)propane dianhydride, butane-1,2,3,4-tetracarboxylic acid, 2,3,5-tricarboxycyclopentylacetic anhydride, 4,4′-[propane-2,2-diylbis(1,4-phenyleneoxy)]diphthalic dianhydride, and 4,4′-(hexafluoroisopropylidene)diphthalic anhydride. These can be used singly or in combination of two or more kinds thereof.

The component (a2) is, for example, as described in Japanese Unexamined Patent Publication No. H9-12712, a compound derived from a dimer acid, which is a dimer of an unsaturated fatty acid such as oleic acid. According to the present embodiment, any dimer diamine can be used without any particular limitation; however, it is preferable that the component (a2) is a compound represented by, for example, general formula (2) and/or general formula (2′) below.

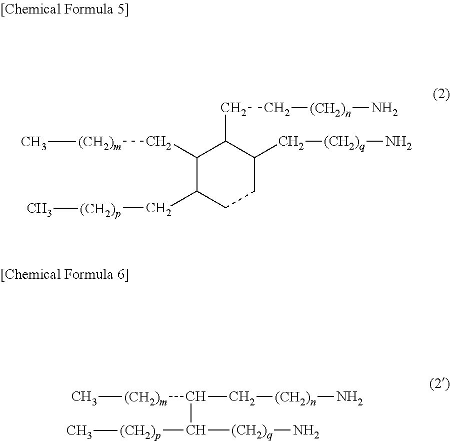

(In formulas (2) and (2′), m, n, p, and q each represent an integer of 1 or more selected so that m+n=6 to 17 and p+q=8 to 19; and a bond represented by a broken line means a carbon-carbon single bond or a carbon-carbon double bond, provided that when the bond represented by a broken line represents a carbon-carbon double bond, the structure of formula (2) or (2′) represents a structure having a number of hydrogen atoms bonded to each of the carbon atoms constituting a carbon-carbon double bond, the number of hydrogen atoms being obtained by subtracting 1 from the number shown in formula (2) or (2′).)

It is preferable that the dimer diamine is represented by the above general formula (2′) from the viewpoints of solubility in organic solvents, heat resistance, adhesiveness, low viscosity, and the like, and a compound represented by the following formula (3) is particularly preferred.

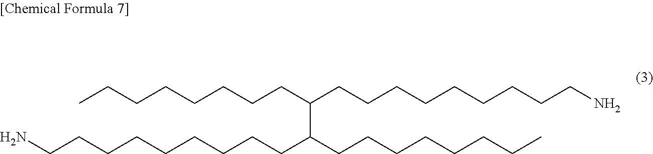

Examples of a commercially available product of the dimer diamine include PRIAMINE 1075 and PRIAMINE 1074 (all manufactured by Croda Japan K.K.). These can be used singly or in combination of two or more kinds thereof.

The component (A) can be produced by various known methods. For example, first, component (a1) and component (a2) are subjected to a polyaddition reaction at a temperature of about 60° C. to 120° C., and preferably 70° C. to 90° C., usually for about 0.1 to 2 hours, and preferably 0.1 to 1.0 hour. Next, the polyaddition product thus obtained is further subjected to an imidization reaction, that is, a dehydration ring-closing reaction, at a temperature of about 80° C. to 250° C., and preferably 100° C. to 200° C., for about 0.5 to 30 hours, and preferably 0.5 to 10 hours. Subsequently, the dehydration ring-closing reaction product and component (a3) are subjected to a maleimidation reaction, that is, a dehydration ring-closing reaction, at a temperature of about 60° C. to 250° C., and preferably 80° C. to 200° C., for about 0.5 to 30 hours, and preferably 0.5 to 10 hours, and thus, an intended component (A) is obtained.

Incidentally, in the imidization reaction or maleimidation reaction, various known reaction catalysts, dehydrating agents, and organic solvents that will be described below can be used. Examples of the reaction catalysts include aliphatic tertiary amines such as triethylamine; aromatic tertiary amines such as dimethylaniline; heterocyclic tertiary amines such as pyridine, picoline, and isoquinoline; and organic acids such as methanesulfonic acid and paratoluenesulfonic acid monohydrate. These can be used singly or in combination of two or more kinds thereof. Examples of the dehydrating agent include aliphatic acid anhydrides such as acetic anhydride; and aromatic acid anhydrides such as benzoic anhydride. These can be used singly or in combination of two or more kinds thereof.

Furthermore, component (A) can be purified by various known methods, and the purity can be increased. For example, first, component (A) dissolved in an organic solvent and pure water are introduced into a separatory funnel. Next, the separatory funnel is shaken and left to stand still. Subsequently, after an aqueous layer and an organic layer are separated, only the organic layer is collected, and thereby the component (A) can be purified.

The molecular weight of the component (A) can be controlled with the mole numbers of the component (a1) and the component (a2), and as the mole number of the component (a1) is smaller than the mole number of the component (a2), the molecular weight can be made smaller. For the purpose of making it feasible to achieve the effects of the present invention, usually, the ratio [mole number of component (a1)]/[mole number of component (a2)] may be in the range of about 0.30 to 0.85, and preferably 0.50 to 0.80.

From the viewpoints of solubility in solvents and heat resistance, the molecular weight of the component (A) is preferably 3000 to 25000, and more preferably 7000 to 20000, as weight average molecular weight. When the weight average molecular weight is 25000 or less, the solubility in organic solvents is satisfactory, and when the weight average molecular weight is 3000 or more, an effect of enhancing heat resistance tends to be sufficiently obtained.

Regarding the component (A) of the present embodiment, a commercially available compound can be used, and specifically, for example, BMI-3000 Commercial Grade (dimer diamine, synthesized from pyromellitic dianhydride and maleic anhydride), BMI-1500, BMI-1700, BMI-5000, and the like manufactured by Designer Molecules Inc. can be suitably used. Regarding the component (A), one kind can be used alone, or two or more kinds can be used in combination.

(Component (B): Silica Particles Surface-Treated with Phenylaminosilane)

Regarding component (B), any silica particles surface-treated with phenylaminosilane, which satisfy the conditions for the average particle diameter, and the maximum aggregation particle size that will be described below can be used without any particular limitation. When the specific silica particles are used, an excellent coefficient of thermal expansion can be obtained while maintaining excellent low dielectric characteristics. It is speculated that an excellent low coefficient of thermal expansion is obtained because when silica particles surface-treated with phenylaminosilane having favorable compatibility with a maleimide group are used, the adhesiveness to the component (A) is enhanced, and when silica particles that satisfy the conditions for the average particle diameter, the maximum aggregation particle size, that will be described below are used, the surface area can be increased even if the blending amount is small.

The average particle diameter of the component (B) is 100 nm or less. As a result, an excellent low coefficient of thermal expansion is likely to be obtained.

As the average particle diameter of the component (B), the value of median diameter (d50) at which the cumulative particle size is 50% in a volume cumulative particle size distribution is employed. The average particle diameter can be measured using a laser diffraction and scattering type particle size distribution analyzer.

The maximum aggregation particle size of the component (B) is 20 μm or less. As a result, an excellent low coefficient of thermal expansion is likely to be obtained. From the viewpoint of further lowering the coefficient of thermal expansion, the maximum aggregation particle size of the component (B) may be 18 μm or less or may be 16 μm or less.

A value measured by the method below is adopted as the maximum aggregation particle size of component (B).
(i) The bismaleimide composition is applied onto an Al foil with a release material. The obtained coating film is dried and cured, then cooled to room temperature. The cured coating film is peeled from the Al foil with the release material, obtaining a sheet-like measurement sample.
(ii) The obtained measurement sample was observed using a microscope. An area inside 100 mm×100 mm of the measurement sample was observed, the maximum aggregation particle size was measured of the largest silica aggregate observed in the vicinity of four corners and of the central part (a total of five places) in the area, then average value thereof calculated. The silica aggregate here refers to silica particles aggregated through contact with one another, and the maximum aggregation particle size refers to a diameter when a minimum circle is drawn that includes all silica particles constituting the silica aggregate.

In (i) above, the type, thickness, and the like of the Al foil with a release material to be used is not particularly limited but, for example, SEPANIUM (manufactured by Toyo Aluminium K.K., trade name “50B2-EA(A)4G/M2”, film thickness 50 μm) may be used. Also, the method of applying the bismaleimide composition onto the Al foil with a release material is not particularly limited but, for example, an applicator may be used. Further, the thickness of the coating film is not particularly limited but, for example, it may be applied such that the thickness after drying is 50 μm to 300 μm. Moreover, conditions for drying and curing the coating film are not particularly limited but, for example, it may be put through a drying process using an oven at 130° C. for 20 minutes then cured by heating using an oven at 200° C. for 1 hour.

Although the measuring microscope to be used is not particularly limited in (ii) above, measuring may be performed using, for example, a measuring microscope (manufactured by Mitutoyo Corporation, trade name: MF-U series), while irradiating light from the back surface. Magnification at measurement time is not particularly limited, but measuring may be performed at, for example, 200 to 400 times.

The content of the component (B) is 15% by mass or less based on the total solid content (non-volatile content) of the composition (100% by mass). As a result, an excellent low coefficient of thermal expansion is likely to be obtained. From the viewpoint of reducing both the dielectric characteristics and the coefficient of thermal expansion in a well-balanced manner, the content of the component (B) may be 5% to 15% by mass.

Regarding the component (B), one kind can be used alone, or two or more kinds can be used in combination.

### (Component (C): Organic Solvent)

The component (C) is not particularly limited as long as it dissolves the component (A). As the component (C), for example, aromatic hydrocarbons such as benzene, toluene, xylene, and mesitylene; alcohol-based solvents such as methanol, ethanol, isopropyl alcohol, butanol, pentanol, hexanol, propanediol, and phenol; ketone-based solvents such as acetone, methyl isobutyl ketone, methyl ethyl ketone, pentanone, hexanone, cyclopentanone, cyclohexanone, isophorone, and acetophenone; cellosolves such as methyl cellosolve and ethyl cellosolve; ester-based solvents such as methyl acetate, ethyl acetate, butyl acetate, methyl propionate, and butyl formate; and glycol ether-based solvents such as ethylene glycol mono-n-butyl ether, ethylene glycol mono-isobutyl ether, ethylene glycol mono-tert-butyl ether, diethylene glycol mono-n-butyl ether, diethylene glycol mono-isobutyl ether, triethylene glycol mono-n-butyl ether, and tetraethylene glycol mono-n-butyl ether, can be used. These can be used singly or in combination of two or more kinds thereof. According to a preferred embodiment, it is preferable to use an aromatic hydrocarbon such as toluene or mesitylene, which has high solubility for the component (A), and a ketone-based solvent such as methyl ethyl ketone or methyl isobutyl ketone, which has high dispersibility for the component (B), in combination.

The amount of use of the component (C) is not particularly limited; however, usually, the component (C) may be used to the extent that the non-volatile content of the composition of the present embodiment is about 20% to 65% by mass.

### (Component (D): Polymerization Initiator)

Specific examples of component (D) include an organic peroxide, an imidazole compound, a phosphine compound, and a phosphonium salt compound. These can be used singly or in combination of two or more kinds thereof. Among them, an organic peroxide in particular has an excellent function as a polymerization initiator, and since it is excellent also from the viewpoint of low dielectric characteristics, an organic peroxide is preferred.

Examples of the organic peroxide include methyl ethyl ketone peroxide, methyl cyclohexanone peroxide, methyl acetoacetate peroxide, acetylacetone peroxide, 1,1-bis(t-butylperoxy)-3,3,5-trimethylcyclohexane, 1,1-bis(t-hexylperoxy)cyclohexane, 1,1-bis(t-hexylperoxy)-3,3,5-trimethylcyclohexane, 1,1-bis(t-butylperoxy)cyclohexane, 2,2-bis(4,4-di-t-butylperoxycyclohexyl)propane, 1,1-bis(t-butylperoxy)cyclododecane, n-butyl 4,4-bis(t-butylperoxy)valerate, 2,2-bis(t-butylperoxy)butane, 1,1-bis(t-butylperoxy)-2-methylcyclohexane, t-butyl hydroperoxide, p-menthane hydroperoxide, 1,1,3,3-tetramethylbutyl hydroperoxide, t-hexyl hydroperoxide, dicumyl peroxide, 2,5-dimethyl-2,5-bis(t-butylperoxy)hexane, α,α′-bis(t-butylperoxy)diisopropylbenzene, t-butyl cumyl peroxide, di-t-butyl peroxide, 2,5-dimethyl-2,5-bis(t-butylperoxy)hexyne-3, isobutyryl peroxide, 3,5,5-trimethylhexanoyl peroxide, octanoyl peroxide, lauroyl peroxide, cinnamic acid peroxide, m-toluoyl peroxide, benzoyl peroxide, diisopropyl peroxydicarbonate, bis(4-t-butylcyclohexyl) peroxydicarbonate, di-3-methoxybutyl peroxydicarbonate, di-2-ethylhexyl peroxydicarbonate, di-sec-butyl peroxydicarbonate, di(3-methyl-3-methoxybutyl) peroxydicarbonate, di(4-t-butylcyclohexyl) peroxydicarbonate, α,α′-bis(neodecanoylperoxy)diisopropylbenzene, cumyl peroxyneodecanoate, 1,1,3,3-tetramethylbutyl peroxyneodecanoate, 1-cyclohexyl-1-methylethyl peroxyneodecanoate, t-hexyl peroxyneodecanoate, t-butyl peroxyneodecanoate, t-hexyl peroxypivalate, t-butyl peroxypivalate, 2,5-dimethyl-2,5-bis(2-ethylhexanoylperoxy)hexane, 1,1,3,3-tetramethylbutyl peroxy-2-ethylhexanoate, peroxy-2-ethylhexanoate, t-hexyl 1-cyclohexyl-1-methylethyl peroxy-2-ethylhexanoate, t-butyl peroxy-2-ethylhexanoate, t-butyl peroxyisobutyrate, t-butyl peroxymaleic acid, t-butyl peroxylaurate, t-butyl peroxy-3,5,5-trimethylhexanoate, t-butyl peroxyisopropyl monocarbonate, t-butyl peroxy-2-ethylhexyl monocarbonate, 2,5-dimethyl-2,5-bis(benzoylperoxy)hexane, t-butyl peroxyacetate, t-hexyl peroxybenzoate, t-butyl peroxy-m-toluoyl benzoate, t-butyl peroxybenzoate, bis(t-butylperoxy)isophthalate, t-butyl peroxyallyl monocarbonate, and 3,3′,4,4′-tetra(t-butylperoxycarbonyl)benzophenone. These can be used singly or in combination of two or more kinds thereof. Among these organic peroxides, dicumyl peroxide, 2,5-dimethyl-2,5-bis(t-butylperoxy)hexane, α,α′-bis(t-butylperoxy)diisopropylbenzene, and the like are preferred.

Examples of the imidazole compound include 2-ethyl-4-methylimidazole, 2-methylimidazole, 2-ethylimidazole, 2,4-dimethylimidazole, 2-undecylimidazole, 2-heptadecylimidazole, 2-phenylimidazole, 2-phenyl-4-methylimidazole, 1-benzyl-2-methylimidazole, 2-phenyl-4,5-dihydroxymethylimidazole, 2-phenyl-4-methyl-5-hydroxymethylimidazole, 1-vinyl-2-methylimidazole, 1-propyl-2-methylimidazole, 2-isopropylimidazole, 1-cyanomethyl-2-methylimidazole, 1-cyanoethyl-2-ethyl-4-methylimidazole, 1-cyanoethyl-2-undecylimidazole, and 1-cyanoethyl-2-phenylimidazole. Among them, 1-cyanoethyl-2-phenylimidazole and 2-ethyl-4-methylimidazole have high solubility with the composition of the present embodiment and are preferable. These can be used singly or in combination of two or more kinds thereof.

Examples of the phosphine compound include primary phosphine, secondary phosphine, and tertiary phosphine. Specific examples of the primary phosphine include alkylphosphines such as ethylphosphine and propylphosphine; and phenylphosphine. Specific examples of the secondary phosphine include dialkylphosphines such as dimethylphosphine and diethylphosphine; and secondary phosphines such diphenylphosphine, methylphenylphosphine, and as ethylphenylphosphine. Examples of the tertiary phosphine include trialkylphosphines such as trimethylphosphine, triethylphosphine, tributylphosphine, and trioctylphosphine; tricyclohexylphosphine, triphenylphosphine, alkyldiphenylphosphine, dialkylphenylphosphine, tribenzylphosphine, tritolylphosphine, tri-p-styrylphosphine, tris(2,6-dimethoxyphenyl)phosphine, tri-4-methylphenylphosphine, tri-4-methoxyphenylphosphine, and tri-2-cyanoethylphosphine. Among them, tertiary phosphine is preferably used. These can be used singly or in combination of two or more kinds thereof.

Examples of the phosphonium salt compound include a tetraphenylphosphonium salt, an alkyltriphenylphosphonium salt, and a compound having a tetraalkylphosphonium or the like, and specific examples include tetraphenylphosphonium thiocyanate, tetraphenylphosphonium tetra-p-methylphenyl borate, butyltriphenylphosphonium thiocyanate, tetraphenylphosphonium phthalate, tetrabutylphosphonium 1,2-cyclohexyldicarboxylate, tetrabutylphosphonium 1,2-cyclohexyldicarboxylate, and tetrabutylphosphonium laurate. These can be used singly or in combination of two or more kinds thereof.

The content of the component (D) is not particularly limited; however, the content is preferably 0.1 to 10.0 parts by mass, and more preferably 1.0 to 5.0 parts by mass, with respect to 100 parts by mass of the component (A).

Preparation of the composition of the present embodiment is carried out according to a generally employed method. Regarding the preparation method, for example, methods such as melt mixing, powder mixing, and solution mixing may be mentioned. Furthermore, at this time, for example, a flame retardant, an ion trapping agent, an oxidation inhibitor, an adhesiveness imparting agent, a stress lowering agent, a colorant, and a coupling agent may be incorporated, in addition to the essential components of the present embodiment, to the extent that does not impair the effects of the present invention. Furthermore, the composition of the present embodiment may also include a resin other than the component (A), such as an epoxy resin, an acrylate compound, a vinyl compound, a benzoxazine compound, or a bismaleimide compound.

### (Flame Retardant)

A flame retardant is added to impart flame retardancy, and any known flame retardants can all be used without particular limitations. Examples of the flame retardant include a phosphazene compound, a silicon compound, talc carrying zinc molybdate, zinc oxide carrying zinc molybdate, aluminum hydroxide, magnesium hydroxide, and molybdenum oxide. These can be used singly or in combination of two or more kinds thereof.

### (Ion Trapping Agent)

An ion trapping agent is added to capture ion impurities that are included in a liquid resin composition and to prevent thermal degradation and hygroscopic degradation. Any known ion trapping agent can all be used without particular limitations. Examples of the ion trapping agent include hydrotalcites, a bismuth hydroxide compound, and rare earth oxides. These can be used singly or in combination of two or more kinds thereof.

### <Cured Product>

A cured product of the present embodiment is a product obtained by curing the composition of the present embodiment. Specifically, the cured product can be obtained by heat-treating the composition at about 150° C. to 250° C. for about 5 minutes to 5 hours.

The shape of the cured product of the present embodiment is not particularly limited; however, in the case of supplying the cured product for a use application of adhering a base material sheet, the cured product can be produced into a sheet form having a film thickness of usually about 1 to 100 μm, and preferably about 3 to 50 μm, while the film thickness can be appropriately adjusted depending on the use application.

### <Sheet>

A sheet of the present embodiment is obtained by applying the composition of the present embodiment on a base material and drying the composition. Examples of the base material include organic base materials such as polyimide, a polyimide-silica hybrid, polyamide, polyethylene (PE), polypropylene (PP), polyethylene terephthalate (PET), polyethylene naphthalate (PEN), a polymethyl methacrylate resin (PMMA), a polystyrene resin (PSt), a polycarbonate resin (PC), an acrylonitrile-butadiene-styrene resin (ABS), and an aromatic polyester resin obtainable from ethylene terephthalate, phenol, phthalic acid, hydroxynaphthoic acid, or the like and para-hydroxybenzoic acid (so-called liquid crystal polymer: “Vecstar” manufactured by Kuraray Co., Ltd., or the like), and among these, from the viewpoints of heat resistance, dimensional stability, and the like, a polyimide film, especially a polyimide-silica hybrid film is preferred. Furthermore, the thickness of the base material can be appropriately set depending on the use application.

### <Laminated Body>

A laminated body of the present embodiment is obtained by further thermocompression bonding a metal foil to the above-described sheet. Regarding this metal foil, a metal foil formed from a metal such as aluminum, alloy 42, or copper is suitable, and the thickness thereof can be appropriately set depending on the use application. Furthermore, this laminated body may be further heat-treated.

### <Flexible Printed Substrate and Flexible Printed Wiring Board>

A flexible printed substrate of the present embodiment is a product obtained by using the above-described sheet base material or the above-described laminated body, and the flexible printed substrate may also be a product obtained by further sticking the sheet to a metal foil surface of the laminated body. This flexible printed substrate is preferably a flexible printed substrate that uses a polyimide film as an organic base material and a metal foil (especially, copper foil) as an inorganic base material. Then, a flexible printed wiring board is obtained by subjecting the metal surface of the flexible printed substrate to a soft etching treatment to form a circuit, further sticking the sheet thereon, and hot pressing the assembly.

### EXAMPLES

Hereinafter, the present invention will be specifically described by way of Examples; however, the present invention is not intended to be limited to these.

### <Preparation of Bismaleimide Resin (A)>

As a bismaleimide resin (A), BMI-3000 Commercial Grade (dimer diamine, synthesized from pyromellitic dianhydride and maleic anhydride, Mw: about 8000) manufactured by Designer Molecules Inc. was dissolved in toluene to prepare a 60 mass % toluene solution.

### Example 1

In a 225-ml cylindrical-shaped vessel, 100 parts by mass of the solution of bismaleimide resin (A), 6.32 parts by mass of a silica-containing slurry (manufactured by Admatechs Company Limited, trade name: YA050C-KJK, silica particles surface-treated with phenylaminosilane, average particle diameter: 50 nm, non-volatile content: 50% by mass) as component (B), 28.34 parts by mass of methyl isobutyl ketone (MIBK, manufactured by Wako Pure Chemical Industries, Ltd.) as component (C), and 0.6 parts by mass of dicumyl peroxide (DCP, manufactured by NOF Corporation) as component (D) were introduced. Subsequently, the vessel was covered with a lid, the mixture in the vessel was stirred using a homomixer (manufactured by PRIMIX Corporation, trade name: T.K. HOMOMIXER MARK II) at 9000 rpm for 20 minutes, and thereby a composition having a non-volatile content of 47.1% by mass was obtained.

### Examples 2 to 5

Various compositions were obtained in the same manner as in Example 1, except that compounds of the types shown in Table 1 as the component (A), component (B), component (C), and component (D) were respectively used in the amounts of use shown in the same table.

The details of the component (B) in Table 1 are as follows.

YA050C-KJK: Silica-containing slurry (manufactured by Admatechs Company Limited, silica particles surface-treated with phenylaminosilane, average particle diameter: 50 nm, non-volatile content: 50% by mass)

Y100SZ-CK1: Silica-containing slurry (manufactured by Admatechs Company Limited, silica particles surface-treated with phenylaminosilane, average particle diameter: 100 nm, non-volatile content: 50% by mass)

### <Production of Cured Sheet (1)>

The composition of each Example was applied on SEPANIUM (manufactured by Toyo Aluminium K.K., trade name “50B2-EA(A)4G/M2”, film thickness 50 μm) using an applicator such that the thickness after drying would be the value shown in Table 2, and a drying treatment was performed using an oven at 130° C. for 20 minutes. Subsequently, a heating treatment was performed using an oven at 200° C. for 1 hour. After the heating treatment, the resultant was cooled to room temperature, and the composition was peeled off from SEPANIUM to obtain a cured sheet (1).

### <Measurement of the Maximum Aggregation Particle Size>

The maximum aggregation particle size of component (B) was measured using the method below. The results are shown in Table 2.
(I) Compositions obtained in the examples were applied onto SEPANIUM (manufactured by Toyo Aluminium K.K., trade name: “50B2-EA(A)4G/M2”, film thickness 50 μm) using an applicator such that the thickness after drying would be 100 μm, and a drying treatment was performed using an oven at 130° C. for 20 minutes. Subsequently, a heating treatment was performed using an oven at 200° C. for 1 hour. After the heating treatment, the resultant was cooled to room temperature then peeled from the SEPANIUM to obtain a sheet-like measurement sample.
(ii) The obtained measurement sample was observed using a measuring microscope (manufactured by Mitutoyo Corporation, trade name: MF-U series) at a magnification of 200 times, while being irradiated with light from the back surface. An area inside 100 mm×100 mm of the measurement sample was observed, the maximum aggregation particle size was measured of the largest silica aggregate observed in the vicinity of four corners and of the central part (a total of five places) in the area, then average value thereof calculated. The silica aggregate here refers to silica particles aggregated through contact with one another, and the maximum aggregation particle size refers to a diameter when a minimum circle is drawn that includes all silica particles constituting the silica aggregate.

### <Dielectric Constant and Dielectric Loss Tangent>

The composition of each Example was applied on FILMBYNA (registered trademark) (PET film, manufactured by FUJIMORI KOGYO CO., LTD., trade name “NS14”, film thickness 75 μm) using an applicator such that the thickness would be 100 μm after drying, and a drying treatment was performed using an oven at 130° C. for 20 minutes. The sample peeled off from the PET film after drying was irradiated, on both surfaces, with light at 500 mJ/cm2 and 150 mW/cm2 using a metal halide lamp (manufactured by GS Yuasa Corporation, trade name “MAL500NAL”). Subsequently, a heating treatment was performed using an oven at 200° C. for 1 hour. After the heating treatment, the resultant was cooled to room temperature, a specimen having a size of 10 cm×5 cm was produced, and the relative permittivity and the dielectric loss tangent at 10 GHz were measured using a SPDR dielectric resonator (manufactured by Agilent Technologies, Inc.). The results are shown in Table 2.

<Coefficients of Thermal Expansion (CTE) α₁, α₂>

A specimen having a size of 10 mm in length×4 mm in width was produced from the cured sheet (1). Using this specimen, the coefficient of thermal expansion (CTE) was measured using a thermomechanical analyzer (trade name “TMA/SS7100”, manufactured by Hitachi High-Tech Science Corporation). The measurement mode was a tensile mode; the measurement load was 20 mN, 25 mN, or 29.4 mN; the measurement atmosphere was air atmosphere, the conditions for temperature rise and cooling for the 1^{st} run and the 2^{nd} run were set to the following conditions; the measurement result at 40° C. to 55° C. on the 2^{nd} run was designated as a1, and the measurement result at 110° C. to 160° C. was designated as a2. The results are shown in Table 2.
1^{st} run: Temperature was increased from 30° C. to 250° C. at a rate of 5° C./min, and after the temperature rise, the specimen was cooled to 30° C.
2^{nd} run: Temperature was increased from 30° C. to 250° C. at a rate of 5° C./min, and the specimen was maintained at 250° C. for 1 minute.

TABLE 1

| | | Example | | | | |
|---|---|---|---|---|---|---|
| Item | | 1 | 2 | 3 | 4 | 5 |
| Component | BMI-3000CG | 100.0 | 100.0 | 100.0 | 100.0 | 100.0 |
| (A) | | | | | | |
| Component | YA050C-KJK | 6.32 | 13.30 | 21.18 | — | — |
| (B) | Y100SZ-CK1 | — | — | — | 13.33 | 21.18 |
| Component | MIBK | 28.34 | 27.67 | 16.70 | 26.40 | 14.40 |
| (C) | | | | | | |
| Component | DCP | 0.6 | 0.6 | 0.6 | 0.6 | 0.6 |
| (D) | | | | | | |

| | | | | | |
|---|---|---|---|---|---|
| Content of component (B) | 5.0 | 10.0 | 15.0 | 10.0 | 15.0 |
| (mass %) | | | | | |
| Non-volatile content | 47.1 | 47.5 | 51.4 | 47.9 | 52.3 |
| (mass %) | | | | | |

TABLE 2

| | | Example | | | | |
|---|---|---|---|---|---|---|
| Item | | 1 | 2 | 3 | 4 | 5 |
| Maximum aggregation particle size (μm) | | 21.0 | 31.0 | 20.0 | 17.0 | 19.0 |
| Dielectric | Dielectric | 2.7 | 2.7 | 2.6 | 2.5 | 2.6 |
| characteristics | constant (Dk) | | | | | |
| | Dielectric loss | 0.003 | 0.003 | 0.003 | 0.003 | 0.003 |
| | tangent (Df) | | | | | |
| TMA measurement | Thickness (μm) | 106 | 108 | 115 | 97 | 104 |
| conditions | Load (mN) | 20.0 | 29.4 | 29.4 | 29.4 | 29.4 |
| CTE | α₁/α₂ | 70/80 | 62/76 | 57/63 | 41/59 | 41/58 |

### INDUSTRIAL APPLICABILITY

The composition of the present invention not only can lower the dielectric characteristics in the high frequency band but can also lower the coefficient of thermal expansion (CTE). Therefore, the composition is useful not only as an adhesive that is used for the manufacture of printed circuit boards (build-up boards, flexible printed wiring boards, and the like) and copper-clad boards for flexible printed wiring boards but is also useful as an electrically insulating material for a semiconductor interlayer material, a coating agent, a resist ink, a conductive paste, and the like.

1. A bismaleimide composition comprising:
a bismaleimide resin (A) having a structure derived from an aromatic tetracarboxylic acid (a1), a dimer diamine (a2), and a maleic anhydride (a3); and
silica particles (B) surface-treated with phenylaminosilane,
wherein the silica particles (B) have an average particle diameter of 100 nm or less,
the silica particles (B) have a maximum aggregation particle size of 20 μm or less, and
a content of the silica particles (B) is 15% by mass or less based on a total solid content of the composition.

2. The bismaleimide composition according to claim 1, wherein the aromatic tetracarboxylic acid (a1) is a pyromellitic anhydride.

3. The bismaleimide composition according to claim 1, wherein the dimer diamine (a2) is a compound represented by general formula (1) and/or general formula (2) below: 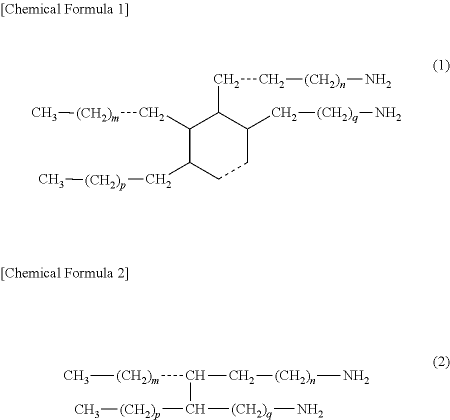
(in formulas (1) and (2), m, n, p, and q each represent an integer of 1 or more selected so that m+n=6 to 17 and p+q=8 to 19; and a bond indicated by a broken line means a carbon-carbon single bond or a carbon-carbon double bond, provided that when the bond indicated by the broken line is a carbon-carbon double bond, the structures of formula (1) and (2) are structures each having a number of hydrogen atoms bonded to each of the carbon atoms constituting the carbon-carbon double bond, the number of hydrogen atoms being obtained by subtracting 1 from the number shown in formula (1) or (2).)

4. The bismaleimide composition according to claim 1, wherein the bismaleimide resin (A) has a weight average molecular weight of 3000 to 25000.

5. The bismaleimide composition according to claim 1, further comprising a polymerization initiator (D).

6. The bismaleimide composition according to claim 5, wherein the polymerization initiator (D) is an organic peroxide.

7. A cured product of the bismaleimide composition according to claim 1.

8. A sheet comprising the bismaleimide composition according to claim 1 and a base material.

9. A laminated body obtained by further thermocompression bonding a metal foil to the sheet according to claim 8.

10. A flexible printed wiring board obtained by using the sheet according to claim 8.

11. A flexible printed wiring board obtained by using the laminated body according to claim 9.
